(19) United States
(12) Patent Application Publication
(10) Pub. No.: US 2012/0012922 A1
(43) Pub. Date: Jan. 19, 2012

(54) SEMICONDUCTOR DEVICE AND METHOD FOR MANUFACTURING THE SAME

(75) Inventor: Tae Su JANG, Gwacheon (KR)

(73) Assignee: Hynix Semiconductor Inc., Icheon (KR)

(21) Appl. No.: 12/945,663

(22) Filed: Nov. 12, 2010

(30) Foreign Application Priority Data
Jul. 15, 2010 (KR) 10-2010-0068377

(51) Int. Cl. H01L 29/78; H01L 21/3205

(52) U.S. Cl. 257/329; 438/657; 257/E21.295; 257/E29.262

(57) ABSTRACT

A semiconductor device and a method of manufacturing the same are provided. Upon forming source or drain at a lower part of the pillar pattern, a silicon oxide layer (barrier layer) is formed inside the pillar pattern to prevent the pillar pattern from being electrically floated. Furthermore, impurities are diffused to a vertical direction (longitudinal direction) of the pillar pattern to overlay junction between the semiconductor substrate and source or drain formed at a lower part of the pillar pattern that leads to improvement of a current characteristic.

### CROSS-REFERENCES TO RELATED APPLICATIONS

Priority to Korean patent application number 10-2010-0068377, filed on Jul. 15, 2010, which is incorporated by reference in its entirety, is claimed.

### BACKGROUND OF THE INVENTION

The present invention relates to a semiconductor device and a method of manufacturing the same.

In recent years, among semiconductor memory devices, a dynamic random access memory (DRAM) device capable of freely inputting and outputting data and being implemented to have large capacity has been widely used.

In general, a memory cell of the DRAM device is composed of an MOS transistor and a storage capacitor. Upon write and read operations of data, the MOS transistor enables charge transfer to the storage capacitor. Further, to prevent the loss of data due to a leakage current, a refresh operation is periodically performed to provide a charge to the storage capacitor.

Here, there is required the storage capacitor capable of sufficiently securing storage capacitance although the size of the storage capacitor is reduced to implement high integration of the DRAM device. Further, there is a need to reduce an area occupied by a unit memory cell to the upmost since the best way of securing price competitiveness is to highly integrate the DRAM device. To do this, a DRAM cell is getting smaller. However, as the size of a semiconductor device has been reduced, characteristics thereof are degraded due to a short-channel effect.

In general, manufacturing the DRAM device is restricted by a minimum lithography feature size in a photographic process. The related art requires an area of 8F2 for each memory cell. A conventional transistor has a channel region of a flat structure. Due to structural problems, the conventional transistor has limitations from aspects of integration and an electric current.

To solve the limitations, the channel region of the conventional transistor has been changed from the flat structure to a recess gate, a fin gate, or a buried gate of a three-dimensional structure. However, as the semiconductor device has been further scaled down, the transistor having a channel region of the three-dimensional structure also has a limitation.

A vertical transistor has been suggested to solve such a limitation. In a general transistor having the flat structure, source/drain regions are formed at left and right sides of a gate to horizontally form a channel region. However, in the vertical transistor, source/drain regions are vertically disposed to form a vertical channel region.

Meanwhile, in a conventional vertical transistor implanting un-doped silicon to form a channel region, it is difficult to control a voltage of a body part. Accordingly, it is difficult to efficiently control a phenomenon such as a punch-through or floating body effect. Namely, when the vertical transistor does not operate, gate induced drain leakage (GIDL) occurs, or holes are accumulated in a body part, which leads to reduction in a threshold voltage of the transistor. This increases the electric current loss of the transistor to discharge a charge stored in a capacitor, which results in the loss of original data.

### BRIEF SUMMARY OF THE INVENTION

Embodiments of the present invention are directed to a semiconductor device and a method of manufacturing the same.

According to an embodiment of the present invention, a method for manufacturing a semiconductor device, includes: forming pillar pattern on a semiconductor substrate; forming a contact at one sidewall of the pillar pattern; etching the pillar pattern exposed through the contact; performing an oxidation process in the exposed pillar pattern to form an oxide layer; implanting impurities into the contact to form a first electrode layer; forming a poly silicon layer pattern in the contact; forming a bit line between the pillar pattern to be connected with the contact; and forming a second electrode layer at a upper part of the pillar pattern.

Forming pillar pattern includes: forming a hard mask layer on the semiconductor substrate; and etching the hard mask layer and the semiconductor substrate by using mask for forming the pillar pattern as mask.

Forming a contact at one sidewall of the pillar pattern includes: forming a liner oxide layer and a liner nitride layer at an entire surface including the pillar pattern; and etching the liner oxide layer and the liner nitride layer until the semiconductor substrate of one of both sidewalls of the pillar pattern is exposed.

Etching the pillar pattern is performed by an isotropic etch method.

Etching the pillar pattern is performed by etching the pillar pattern less than a diameter of the pillar pattern or a half of a critical dimension (CD).

In accordance with an embodiment of the present invention, a method for manufacturing a semiconductor device further includes etching the oxide layer between forming an oxide layer and implanting impurities into the contact.

Etching the oxide layer completely removes an oxide layer of a vertical direction of the pillar pattern and partially removes an oxide layer of a lateral direction of the pillar pattern.

In accordance with an embodiment of the present invention, a method for manufacturing a semiconductor device further includes forming a poly silicon layer and a conductive layer between the pillar pattern after forming the pillar pattern.

Forming a first electrode layer includes: implanting first impurities in the pillar pattern of the exposed contact; and implanting second impurities after moving the oxide layer.

The first and second impurities are an impurity different from that of the semiconductor substrate and the pillar pattern.

The first impurity is light diffusible impurity.

The first impurity is phosphorus.

The second impurity is a heavy low-diffusible impurity.

The second impurity is arsenic.

Forming a poly silicon layer pattern in the contact includes: forming a poly silicon layer at an entire surface including the contact formed at the one sidewall of the pillar pattern; and removing the poly silicon layer using a dry oxidation process.

Forming a bit line includes: forming a bit line electrode layer at an entire surface including the poly silicon layer pattern; and etching the bit line electrode layer using a dry oxidation process.

The bit line electrode layer comprises titanium (Ti), a titanium nitride (TiN) layer, and tungsten (W).

According to an embodiment of the present invention, a semiconductor device includes: a pillar pattern provided on a semiconductor substrate; a contact formed at one sidewall of the pillar pattern; first source/drain electrodes formed in the contact; a poly silicon layer pattern filled in the contact; a bit line connected to the contact between the pillar pattern; and second source/drain electrodes formed at an upper part of the pillar pattern.

Impurities ion-implanted into the first and second source/drain electrodes have a type different from that of the semiconductor substrate.

The bit line electrode layer comprises titanium (Ti), a titanium nitride (TiN) layer, and tungsten (W).

The first source/drain electrodes and the semiconductor substrate are overlapped with each other.

The first source/drain electrodes formed in the contact are formed in a longitudinal direction of the pillar pattern.

### BRIEF DESCRIPTION OF THE DRAWINGS

FIG. 1a to FIG. 1k are cross-sectional views illustrating a method for manufacturing a semiconductor device according to an embodiment of the present invention.

### DESCRIPTION OF EMBODIMENTS

Exemplary embodiments of the present invention are described in detail with reference to the accompanying drawings.

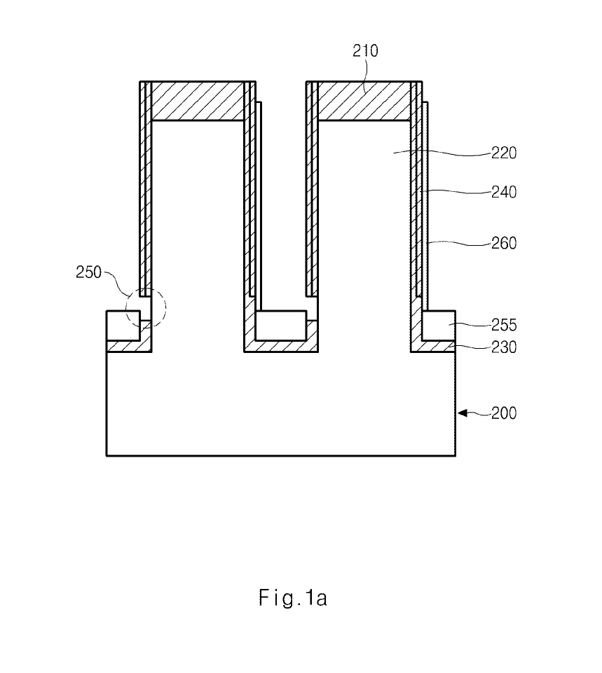

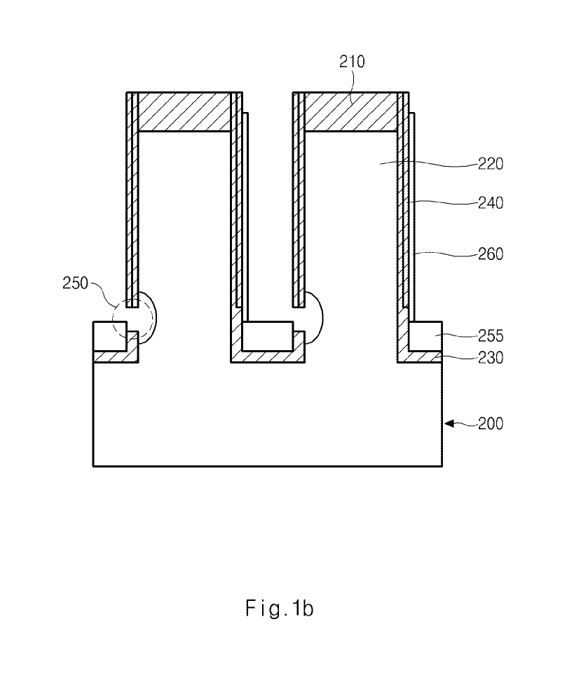

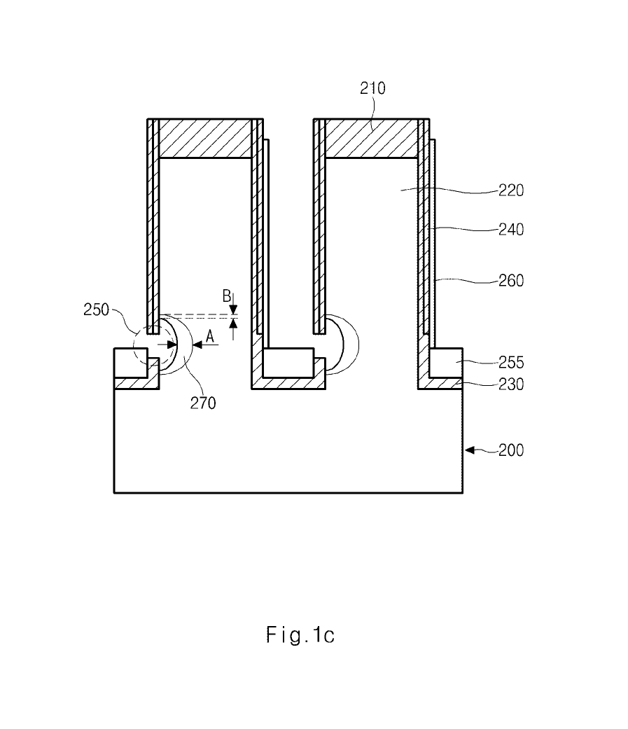

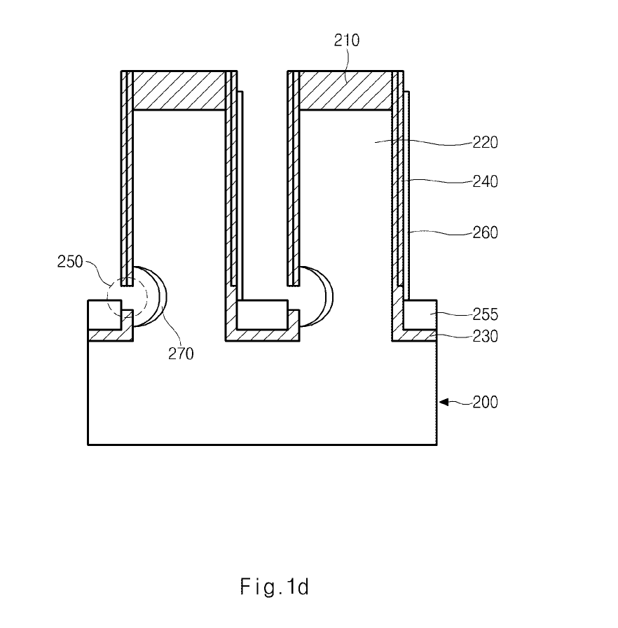

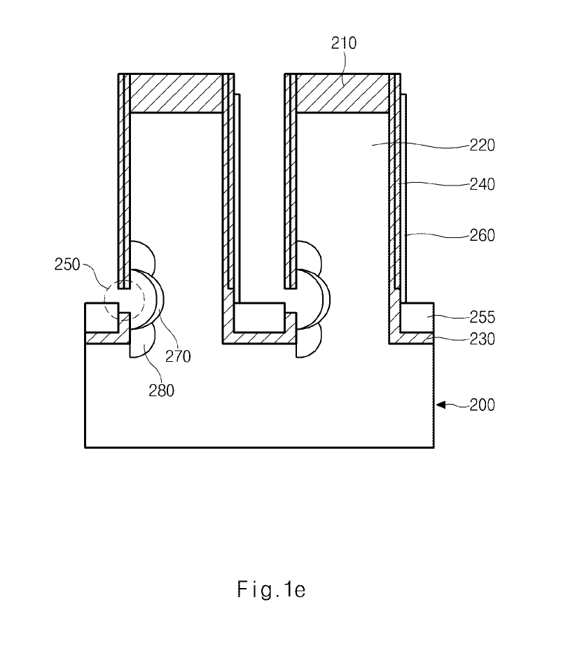

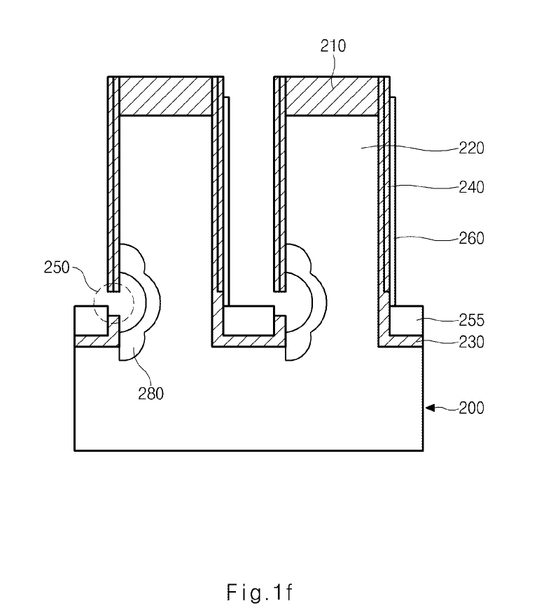

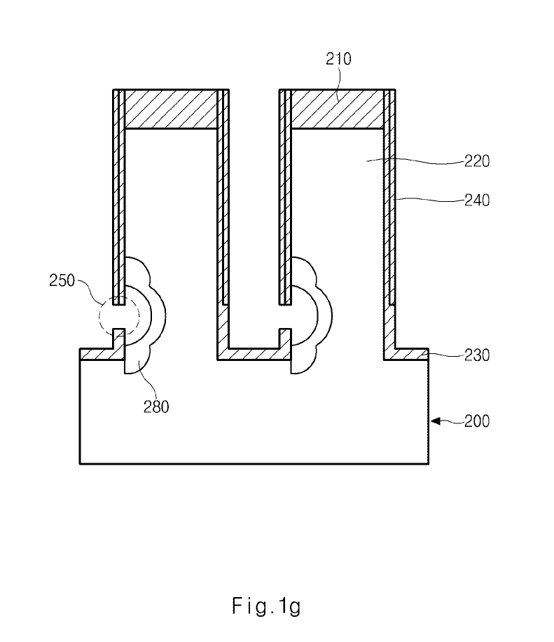

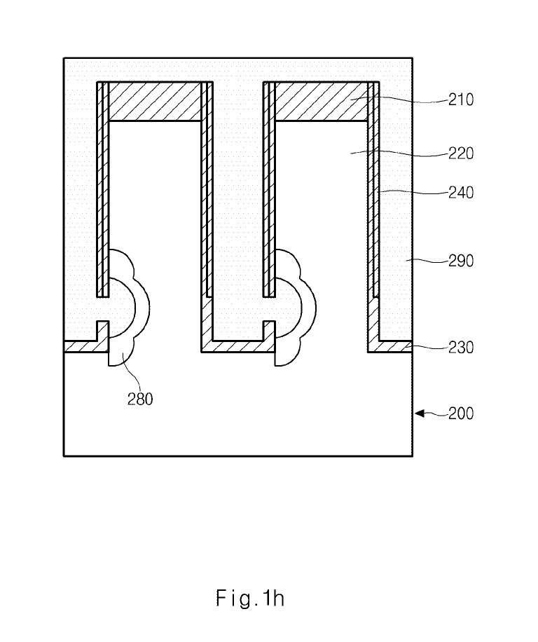

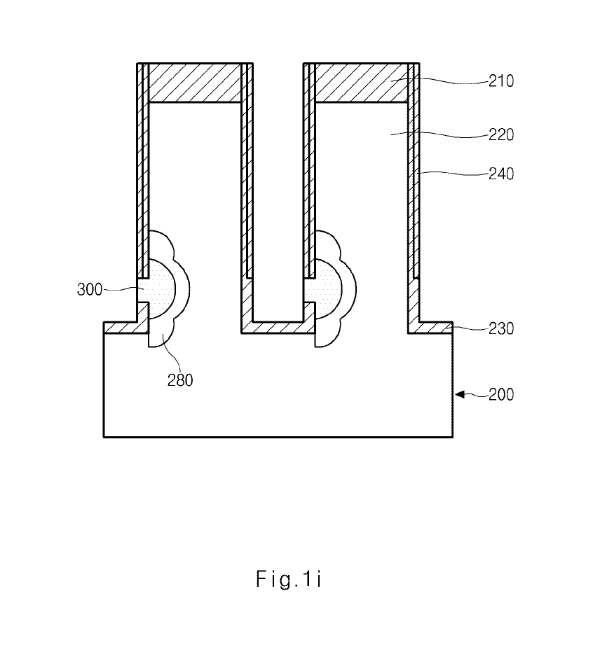

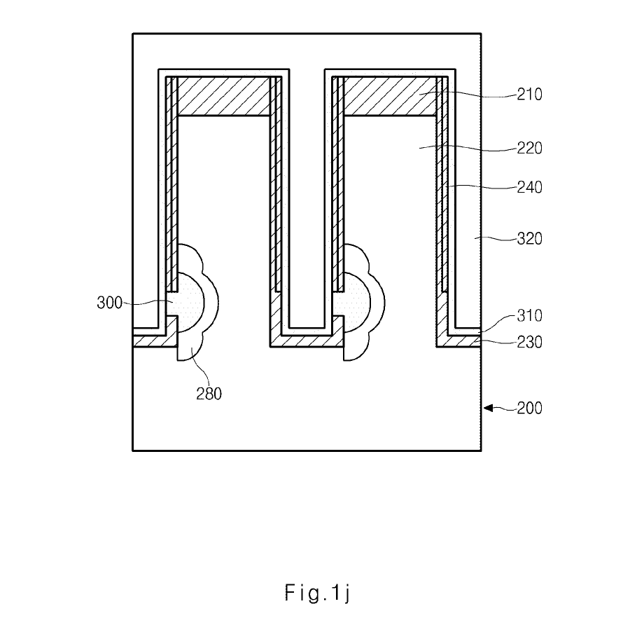

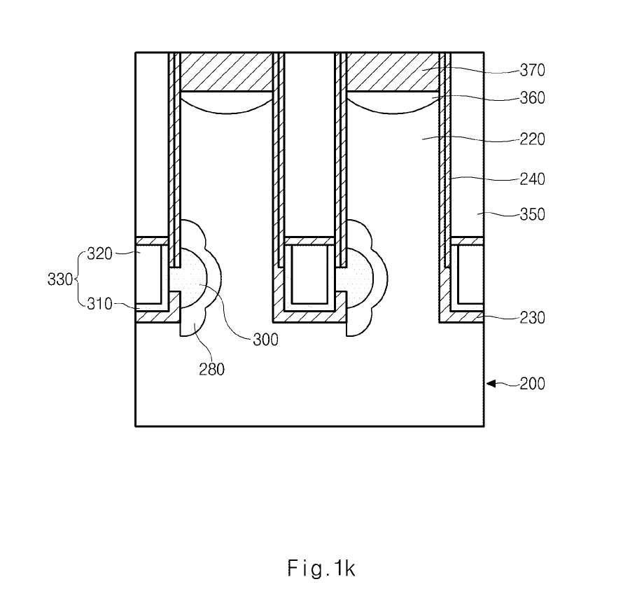

FIG. 1a to FIG. 1k are cross-sectional views illustrating a method for manufacturing a semiconductor device according to an embodiment of the present invention.

Referring to FIG. 1a, a hard mask layer 210 is formed on a semiconductor substrate 200. After forming a photo resist on the hard mask layer 210, a photo resist pattern (not shown) is formed by performing exposure and development processes using a mask for forming a pillar pattern. In this case, it is preferred that the hard mask layer 210 is formed of nitride. The hard mask layer 210 and the semiconductor substrate 200 are etched by using the photo resist pattern as an etch mask to form a pillar pattern 220.

Subsequently, a liner oxide layer 230 and a liner nitride layer 240 are formed on the whole surface of a resultant structure including the pillar pattern 220. At this time, after formation of the liner nitride layer 240, a poly silicon layer 255 is preferably formed at a lower portion of a space between neighboring pillar patterns 220. When forming a contact (or contact opening) in a subsequent process, the poly silicon layer 255 may serve to protect an underlying layer.

Next, until one sidewall of the pillar pattern 220 is exposed, the liner oxide layer 230 and the liner nitride layer 240 are etched, so that a contact opening 250 is formed at the exposed portion of the pillar pattern 220. A conductive layer 260 is deposited on the liner oxide layer 230 and the liner nitride layer 240 disposed over the other sidewall of the pillar pattern 220 where the contact opening 250 is not formed. In this case, the conductive layer 260 may include a titanium (Ti) or titanium nitride (TiN) layer.

Referring to FIG. 1b, the exposed portion of the pillar pattern 220 is partially removed using an etching process. Here, an isotropic etching process using a wet etching process may be performed as the etching process. In this case, it is preferred that the exposed portion of the pillar pattern 220 is etched as much as less than a diameter of the pillar pattern 220 or a half of a critical dimension (CD).

Referring to FIG. 1c, an oxidation process is performed on the etched portion of the pillar pattern 220 to form an oxide layer 270. Here, it is preferred that the oxide layer 270 serves as a diffusion barrier for preventing impurities from diffusing. In this case, because a growth rate of the oxide layer 270 in a lateral direction (region A) of the pillar pattern 220 is higher than that in a vertical direction (region B), the oxide layer 270 is grown more thickly at the inside of the pillar pattern 220. Here, the oxide layer 270 may be formed to have a thickness ranging from 1 nm to 100 nm in the lateral direction.

Referring to FIG. 1d, the oxide layer 270 may be partially etched in such a way that the oxide layer 270 is more quickly removed in the vertical direction than in the lateral direction. At this time, the etching process may be performed in such a way that the oxide layer 270 is etched using a solution of hydrofluoric acid for 1 to 1800 seconds.

Here, the oxide layer 270 is removed more in the vertical direction than in the lateral direction. Accordingly, since N-type impurities are further diffused to the vertical direction in a subsequent process, a vertical gate (semiconductor substrate) and a source/drain can overlap with each other to improve current and gate characteristics. Further, because the oxide layer 270 partially remains in the lateral direction on the pillar pattern 220, it may prevent diffusion upon implantation of impurities and electrical floating of a region in which a channel of the pillar pattern 220 is formed.

Referring to FIG. 1e, impurity ions are implanted into the contact 250 to form a first electrode 280. In this case, impurity ions differing from those of the pillar pattern 220 or the semiconductor substrate 200 may be implanted into the contact opening 250. For example, the pillar pattern 220 or the semiconductor substrate 200 is of a P-type, N-type impurity ions may be implanted into the contact opening 250. At this time, a light diffusible impurity ion such as phosphorus (P) may be used as the N-type impurity ion.

Referring to FIG. 1f, after the oxide layer 270 remaining in the lateral direction of the pillar pattern 220 is removed, N-type impurity ions are implanted into the contact opening 250. Here, the oxide layer 270 may be removed using a wet etching process. A heavy diffusible impurity ion such as arsenic (As) may be used as the N-type impurity ion.

Referring to FIG. 1g, the conductive layer 260 formed on the sidewall of the pillar pattern 220 and the poly silicon layer 225 formed in the space between the pillar patterns 220 are removed.

Referring to FIG. 1h, a poly silicon layer 290 is deposited on the whole surface of a resultant structure where the first electrode 280 is formed, and then the conductive layer 260 and the poly silicon layer 225 are removed. Here, the poly silicon layer 290 fills the etched portion of the pillar pattern 220 at the contact opening 250.

Referring to FIG. 1i, the poly silicon layer 290 is removed using a dry oxidation process to form a poly silicon layer pattern 300 in the contact opening 250. In this case, it is preferred that the dry oxidation process is an anisotropic etching process. The poly silicon layer pattern 300 prevents junction leakage between source/drain electrodes and the pillar pattern 220 and thus improves resistance between the source/drain electrodes and the pillar pattern 220.

Referring to FIG. 1j, after a stacked structure 310 of a titanium (Ti) layer and a titanium nitride (TiN) layer is formed on the hard mask layer 210, the liner oxide layer 230, the liner nitride layer 240, and the poly silicon layer pattern 300, a tungsten (W) layer 320 is deposited.

Referring to FIG. 1k, the stacked structure 310 and the tungsten (W) layer 320 are etched to form a bit line 330 that is connected with the poly silicon layer pattern 300. In this case, the stacked structure 310 and the tungsten (W) layer 320 may be etched using a dry etching process. Subsequently, after an insulating layer 350 is deposited on the bit line 330 disposed between the pillar patterns 220, N-type impurity ions 360 are implanted into an upper portion of the pillar pattern 220 to form a second electrode 370.

As can be seen from the forgoing description, in accordance with the embodiment of the present invention, upon forming a source or drain at a lower portion of the pillar pattern, a silicon oxide layer (barrier layer) is formed inside the pillar pattern to prevent the pillar pattern from being electrically floated. Furthermore, impurities are diffused to a vertical direction (longitudinal direction) of the pillar pattern to overlay the semiconductor substrate and a source or drain formed at the lower portion of the pillar pattern, which results in improving a current characteristic of a semiconductor device.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a semiconductor device, comprising:
forming a pillar pattern over a semiconductor substrate;
forming a contact opening at one sidewall of the pillar pattern;
etching a portion of the pillar pattern that is exposed by the contact opening;
performing an oxidation process on the exposed portion of the pillar pattern to form an oxide layer in the pillar pattern;
providing impurities into the pillar pattern through the contact opening to form a first electrode layer in the pillar pattern;
forming a poly silicon layer pattern by filling the etched portion of the pillar pattern;
forming a bit line at a lower portion of a space between the pillar pattern and an adjacent pillar pattern, the bit line being coupled with the poly silicon layer pattern; and
forming a second electrode layer at an upper portion of the pillar pattern.

2. The method of claim 1, wherein the forming-a-pillar-pattern comprises:
forming a hard mask layer over the semiconductor substrate; and
etching the hard mask layer and the semiconductor substrate using a mask to form the pillar pattern.

3. The method of claim 1, wherein the forming-a-contact-opening comprises:
forming a liner oxide layer and a liner nitride layer over the whole surface of a structure including the pillar pattern; and
etching the liner oxide layer and the liner nitride layer until the semiconductor substrate at the one sidewall of the pillar pattern is exposed.

4. The method of claim 1, wherein the etching-a-portion-of-the-pillar-pattern is performed by an isotropic etch process.

5. The method of claim 1, wherein the etching-a-portion-of-the-pillar-pattern is performed by etching the pillar pattern no more than a diameter of the pillar pattern or a half of a critical dimension (CD).

6. The method of claim 1, further comprising etching the oxide layer after performing the oxidation process and before providing the impurities into the pillar pattern.

7. The method of claim 6, wherein the etching-the-oxide-layer at least substantially removes a portion of the oxide layer in a vertical direction of the pillar pattern and partially removes a portion of the oxide layer in a lateral direction of the pillar pattern.

8. The method of claim 1, further comprising forming a polysilicon layer and a conductive layer in a space between the pillar pattern and an adjacent pillar pattern.

9. The method of claim 1, wherein the forming-a-first-electrode-layer comprises:
implanting first impurities into the pillar pattern through the contact opening;
removing the oxide layer; and
implanting second impurities into the pillar pattern.

10. The method of claim 9, wherein the first and second impurities are a different conductivity type from that of the semiconductor substrate and the pillar pattern.

11. The method of claim 9, wherein the first impurities include light diffusible impurities.

12. The method of claim 9, wherein the first impurities include phosphorus.

13. The method of claim 9, wherein the second impurities include heavy diffusible impurities.

14. The method of claim 9, wherein the second impurities include arsenic.

15. The method of claim 1, wherein the forming-a-poly-silicon-layer-pattern comprises:
forming a poly silicon layer over a surface of a structure including the first electrode layer formed in the pillar pattern; and
removing the poly silicon layer using a dry etching process so that the poly silicon layer remains in the etched portion of the pillar pattern.

16. The method of claim 1, wherein the forming-a-bit-line comprises:
forming a bit line electrode layer in the space between the pillar patterns after forming the poly silicon layer pattern; and
etching an upper portion of the bit line electrode layer using a dry etching process.

17. The method of claim 16, wherein the bit line electrode layer comprises a titanium (Ti) layer, a titanium nitride (TiN) layer, and a tungsten (W) layer.

18. A semiconductor device comprising:
a pillar pattern formed by partially etching a semiconductor substrate;
a contact opening disposed at one sidewall of the pillar pattern;
a first source/drain electrode disposed in the contact;
a polysilicon layer pattern filled in the contact;
a bit line coupled to the contact and disposed between pillar patterns; and
a second source/drain electrode formed at an upper portion of the pillar pattern.

19. The semiconductor device of claim 18, wherein impurity ions implanted into the first and second source/drain electrodes have a different conductivity type from that of the semiconductor substrate.

20. The semiconductor device of claim 18, wherein the bit line is formed of a titanium (Ti) layer, a titanium nitride (TiN) layer, and a tungsten (W) layer.

21. The semiconductor device of claim 18, wherein the first source/drain electrode and the semiconductor substrate overlap with each other.

22. The semiconductor device of claim 18, wherein the first source/drain electrode formed in the contact is formed in a longitudinal direction of the pillar pattern.
